(19) United States
(12) Patent Application Publication
(10) Pub. No.: US 2026/0068452 A1
(43) Pub. Date: Mar. 5, 2026

(54) DRIVING BACKPLANE AND DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventor: Jixiang GONG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 19/041,950

(22) Filed: Jan. 30, 2025

Related U.S. Application Data
(63) Continuation of application No. PCT/CN2024/129246, filed on Nov. 1, 2024.

(30) Foreign Application Priority Data
Aug. 30, 2024 (CN) 202411209487.4

(51) Int. Cl. H10K 59/131; G09G 3/3258; H10K 59/121; H10K 59/126; H10K 59/65

(52) U.S. Cl. CPC H10K 59/131; G09G 3/3258; H10K 59/1213; H10K 59/1216; H10K 59/126; H10K 59/65; G09G 2300/0408; G09G 2300/0819; G09G 2300/0852; G09G 2300/0861; G09G 2320/0233

(57) ABSTRACT

A driving backplane and a display panel are provided by the present application. The driving backplane includes a substrate and a first semiconductor layer, a first conductive layer, a second semiconductor layer, and a second conductive layer arranged on the substrate. The first semiconductor layer forms an active part of a polysilicon transistor. The first conductive layer forms a gate of the polysilicon transistor. The second semiconductor layer forms an active part of an oxide transistor and a first electrode plate of a storage capacitor. The second conductive layer forms a gate of the oxide transistor.

### CROSS-REFERENCE TO RELATED APPLICATIONS

The present application is a continuation application of an International Application No. PCT/CN2024/129246, filed on Nov. 1, 2024, which claims priority to Chinese Application No. 202411209487.4, filed on Aug. 30, 2024, both of which are incorporated herein by reference in their entireties.

### TECHNICAL FIELD

The present application relates to the technical field of displays, and in particular to a driving backplane and a display panel.

### BACKGROUND

With a continuous development of display technology, people have higher and higher requirements on the resolution, power consumption, and image quality of display products. In order to meet these requirements, a low temperature polycrystalline oxide (LTPO) technology is often configured to make a pixel driving circuit in a driving backplane of a display product. Cryogenic polysilicon oxide technology is provided with the advantages of high mobility of low temperature poly silicon (LTPS) and low leakage current of oxide semiconductors such as indium gallium zinc oxide (IGZO), and has the advantages of high resolution, high reaction speed, high brightness, high opening rate, low power consumption, and refresh rate of 1Hz to 120 Hz.

However, two kinds of thin film transistor (TFT) devices should be prepared in a driving backplane having the low temperature polycrystalline oxide. Thus, it is provided with many film layers in the driving backplane, which leads to complex process, low preparation efficiency, and high production cost.

### SUMMARY

The present application provides a driving backplane and a display panel to alleviate technical problems, such as a need of many film layers, a complex process, a low preparation efficiency and a high production cost, of a driving backplane having a low temperature polycrystalline oxide.

Technical solutions provided in the present application are as follows.

In a first aspect, embodiments of the present application provide a driving backplane, and the driving backplane includes a display area and a non-display area located on a side of the display area. The display area is provided with multiple sub-pixels arranged in an array, each of the sub-pixels includes a polysilicon transistor, an oxide transistor, and a storage capacitor. The driving backplane further includes:
a substrate;
a first semiconductor layer, arranged on a side of the substrate, in which the first semiconductor layer includes an active part of the polysilicon transistor;
a first conductive layer, arranged on a side, of the first semiconductor layer, away from the substrate, in which the first conductive layer includes a gate of the polysilicon transistor;
a second semiconductor layer, arranged on a side, of the first conductive layer, away from the substrate, in which the second semiconductor layer includes a first electrode plate of the storage capacitor and an active part of the oxide transistor, and the first electrode plate of the storage capacitor is arranged to be corresponding to the gate of the polysilicon transistor;
a second conductive layer, arranged on a side, of the second semiconductor layer, away from the substrate, in which the second conductive layer includes a gate of the oxide transistor; and
a third conductive layer, arranged on a side, of the second conductive layer, away from the substrate, in which the third conductive layer includes a source and a drain of the polysilicon transistor, and a source and a drain of the oxide transistor;
in which, the non-display area includes a fan-out area arranged to be close to the display area, the fan-out area is provided with a first fan-out wiring and a second fan-out wiring arranged alternately, the first fan-out wiring is located at least one layer of the first conductive layer or the second conductive layer, the second fan-out wiring is located at least one layer of the second conductive layer or the third conductive layer, the first fan-out wiring, and the second fan-out wiring are located in different layers, and an impedance of the first fan-out wiring is equal to an impedance of the second fan-out wiring.

In a second aspect, embodiments of the present application further provide a display panel, and the display panel includes a light-emitting component and a driving backplane as described in any one of the embodiments described above, and the light-emitting component is arranged on the driving backplane.

### BRIEF DESCRIPTION OF THE DRAWINGS

In order that the technical solutions in the embodiments of the present application may be explained more clearly, a brief description is given below to the accompanying drawings for use in the description of the embodiments. Obviously, the accompanying drawings in the following description are merely some of the embodiments of the present application, and other drawings may be obtained based on these drawings without involving any creative efforts to those skilled in the art.

FIG. 1 is a schematic plan view of a first structure of a driving backplane according to an embodiment of the present application.

FIG. 2 is a schematic diagram of a structure of partial films in a driving backplane according to an embodiment of the present application.

FIG. 3 is a schematic diagram of a detailed structure in a fan-out area in FIG. 1.

FIG. 4 is a schematic diagram of a first cross-sectional structure of the fan-out area taken along a line M-M′ in FIG. 3.

FIG. 5 is a schematic diagram of a second cross-sectional structure of the fan-out area taken along the line M-M′ in FIG. 3.

FIG. 6 is a schematic plan view of a second structure of a driving backplane according to an embodiment of the present application.

FIG. 7 is a schematic diagram of a detailed structure of an edge wiring of a holing area in FIG. 6.

FIG. 8 is a circuit diagram of a sub-pixel according to an embodiment of the present application.

### DETAILED DESCRIPTION

The descriptions of each of the following embodiments are illustrated with reference to the accompanying drawings to illustrate the specific embodiments of the present application that may be configured to implement. The directional terms mentioned in the present application, such as [up], [down], [front], [rear], [left], [right], [inside], [outside], [side surface], etc., are only the directions referring to the accompanying drawings. Therefore, the directional terms are configured to explain and understand the present application, rather than to limit the present application. In the drawings, the units with similar structures are represented by the same numeral. In the accompanying drawings, in order to clearly understand and facilitate the description, the thickness of some layers and areas is exaggerated. The dimensions and thickness of each component shown in the accompanying drawings are arbitrary, but the present application is not limited to this.

Embodiments of the present application provide a driving backplane, and the driving backplane includes a display area and a non-display area located on a side of the display area. The display area is provided with multiple sub-pixels arranged in an array, each of the sub-pixels includes a polysilicon transistor, an oxide transistor and a storage capacitor. The driving backplane further includes:
a substrate;
a first semiconductor layer, arranged on a side of the substrate, in which the first semiconductor layer includes an active part of the polysilicon transistor;
a first conductive layer, arranged on a side, of the first semiconductor layer, away from the substrate, in which the first conductive layer includes a gate of the polysilicon transistor;
a second semiconductor layer, arranged on a side, of the first conductive layer, away from the substrate, in which the second semiconductor layer includes a first electrode plate of the storage capacitor and an active part of the oxide transistor, and the first electrode plate of the storage capacitor is arranged to be corresponding to the gate of the polysilicon transistor;
a second conductive layer, arranged on a side, of the second semiconductor layer, away from the substrate, in which the second conductive layer includes a gate of the oxide transistor; and
a third conductive layer, arranged on a side, of the second conductive layer, away from the substrate, in which the third conductive layer includes a source and a drain of the polysilicon transistor, and a source and a drain of the oxide transistor;
in which, the non-display area includes a fan-out area arranged to be close to the display area, the fan-out area is provided with a first fan-out wiring and a second fan-out wiring arranged alternately, the first fan-out wiring is located at least one layer of the first conductive layer or the second conductive layer, the second fan-out wiring is located at least one layer of the second conductive layer or the third conductive layer, the first fan-out wiring, and the second fan-out wiring are located in different layers, and an impedance of the first fan-out wiring is equal to an impedance of the second fan-out wiring.

In an embodiment, the first fan-out wiring is located in the first conductive layer, and the second fan-out wiring is located in the second conductive layer. The ratio of the length of the first fan-out wiring to its cross-sectional area is a first ratio. The ratio of the length of the second fan-out wiring to a cross-sectional area of the second fan-out wiring is a second ratio, and the second ratio is equal to the first ratio.

In an embodiment, the second fan-out wiring includes a blocking part and a conductive part located on a side, of the blocking part, away from the substrate. A thickness of the conductive part is equal to a thickness of the first fan-out wiring.

In an embodiment, the material of the conductive part includes molybdenum, material of the blocking part includes titanium, and the material of the first fan-out wiring is the same as the material of the conductive part.

In an embodiment, the first fan-out wiring includes a first sub-wiring located in the first conductive layer and a second sub-wiring located in the second conductive layer. The first sub-wiring and the second sub-wiring are connected in parallel, and the second fan-out wiring is located in the third conductive layer.

In an embodiment, an orthographic projection, of the first sub-wiring, on the substrate overlaps with an orthographic projection, of the second sub-wiring, on the substrate.

In an embodiment, an orthographic projection, of the first fan-out wiring, on the substrate is at least partially overlapped with an orthographic projection, of the second fan-out wiring, on the substrate.

In an embodiment, the driving backplane further includes a fourth conductive layer arranged between the substrate and the first semiconductor layer. The fourth conductive layer includes a first light-shielding part arranged to be corresponding to the active part and a second light-shielding part arranged to be corresponding to the active part.

In an embodiment, the second light-shielding part is electrically connected to the gate of the oxide transistor.

In an embodiment, both the first fan-out wiring and the second fan-out wiring extend along a first direction, and the first fan-out wiring and the second fan-out wiring are staggered in the first direction. The driving backplane further includes a holing area arranged in the display area, the first conductive layer further includes a first winding line located in the display area, and the second conductive layer further includes a second winding line located in the display area. Both the first winding line and the second winding line extend along the first direction;

The driving backplane further includes a first winding line group and a second winding line group. The first winding line group is configured to cooperate with the second winding line group to surround the holing area. The first winding line group and the second winding line group both include multiple first winding lines and second winding lines alternately arranged in a second direction. The first direction is different from the second direction, and an angle between the second direction and the first direction is greater than 0 degree and less than or equal to 90 degrees.

In an embodiment, a gap is provided between the orthographic projection, of the first winding, on the substrate and the orthographic projection, of the second winding, on the substrate.

In an embodiment, each sub-pixel further includes:
a switching transistor, in which a gate of the switching transistor is connected with a first scanning signal line, and a first electrode of the switching transistor is connected with a data line;
a driving transistor, in which a first electrode of the driving transistor and a second electrode of the switching transistor are connected to a first node;
a compensation transistor, in which a gate of the compensation transistor is connected with a second scanning signal line, a first electrode of the compensation transistor is connected with a gate of the driving transistor at a second node, and a second electrode of the compensation transistor is connected with a second electrode of the driving transistor;
a first initialization transistor, in which a gate of the first initialization transistor is connected with a third scanning signal line, a first electrode of the first initialization transistor is connected with a first initialization signal line, and a second electrode of the first initialization transistor is connected with a gate of the driving transistor at the second node;
a first light-emitting control transistor, in which a gate of the first light-emitting control transistor is connected with a light-emitting control signal line, a first electrode of the first light-emitting control transistor is connected with a high potential power line, and a second electrode of the first light-emitting control transistor is connected with the first electrode of the driving transistor at the first node;
a second light-emitting control transistor, in which a gate of the second light-emitting control transistor is connected with the light-emitting control signal line, and a first electrode of the second light-emitting control transistor is connected with a second electrode of the driving transistor at a third node;
a second initialization transistor, in which a gate of the second initialization transistor is connected with a fourth scanning signal line, a first electrode of the second initialization transistor is connected with a second initialization signal line, and a second electrode of the second initialization transistor is connected with a second electrode of the second light-emitting control transistor at a fourth node;
a third initialization transistor, in which a gate of the third initialization transistor is connected with the fourth scanning signal line, a first electrode of the third initialization transistor is connected with a third initialization signal line, and a second electrode of the third initialization transistor is connected with the first electrode of the driving transistor at the first node;
a first capacitor, in which one electrode plate of the first capacitor is connected with the high potential power line, and another electrode plate of the first capacitor is connected with the gate of the driving transistor at the second node; and
a second capacitor, in which one electrode plate of the second capacitor is connected with the first scanning signal line, and another electrode plate of the second capacitor is connected with the second electrode of the first initialization transistor;
in which, the polysilicon transistor includes the switching transistor, the driving transistor, the first light-emitting control transistor, the second light-emitting control transistor, the second initialization transistor, and the third initialization transistor; the oxide transistor includes the compensation transistor and the first initialization transistor; and the first capacitor is the storage capacitor, and the second capacitor is a boost capacitor.

In an embodiment, the first winding and the second winding can be respectively at least one of the first scanning signal line, the second scanning signal line, the third scanning signal line, the fourth scanning signal line, the light-emitting control signal line, the first initialization signal line, the second initialization signal line, or the third initialization signal line.

In an embodiment, a first electrode plate of the storage capacitor is arranged to be corresponding to the gate of the driving transistor.

Embodiments of the present application further provides a display panel, and the display panel includes a light-emitting component and a driving backplane as described in any one of the embodiments described above, and the light-emitting component is arranged on the driving backplane.

In the driving backplane and the display panel provided in the present application, the driving backplane includes multiple sub-pixels arranged in an array in the display area. Each of the sub-pixels includes a polysilicon transistor, an oxide transistor, and a storage capacitor. The driving backplane further includes a substrate and a first semiconductor layer, a first conductive layer, a second semiconductor layer, a second conductive layer, and a third conductive layer arranged on the substrate. The first semiconductor layer forms the active part of the polysilicon transistor, the first conductive layer forms the gate of the polysilicon transistor, the second semiconductor layer forms the active part of the oxide transistor and the first electrode plate of the storage capacitor, the second conductive layer forms the gate of the oxide transistor, and the third conductive layer forms a source and a drain of the polysilicon transistor and a source and a drain of the oxide transistor. As such, by setting the first electrode plate of the storage capacitor and the active part of the oxide transistor in the same layer, a conductive layer between the second semiconductor layer and the first conductive layer can be removed, so that film layers of the driving backplane can be simplified, the preparation process can be simplified, the preparation efficiency can be improved, and the production cost can be reduced. In addition, a first fan-out wiring is formed on at least one of the first conductive layer or the second conductive layer, and a second fan-out wiring is formed on at least one of the second conductive layer or the third conductive layer. The first fan-out wiring and the second fan-out wiring are located in different layers, and an impedance of the first fan-out wiring is equal to an impedance of the second fan-out wiring, so as to improve the display uniformity.

The following is combined with the accompanying drawings and the specific embodiments to explain in detail the driving backplane and the display panel of the present application.

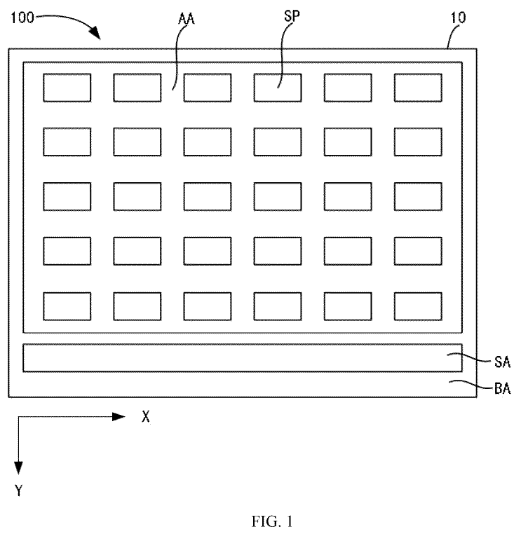

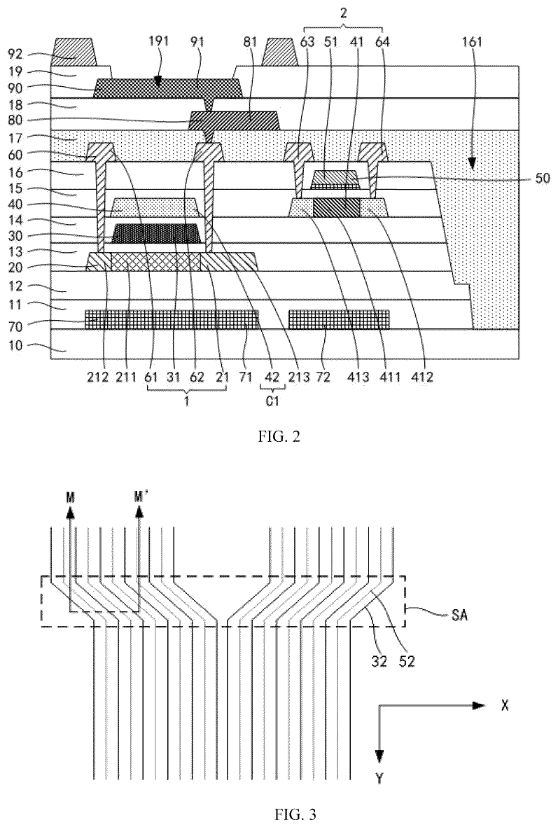

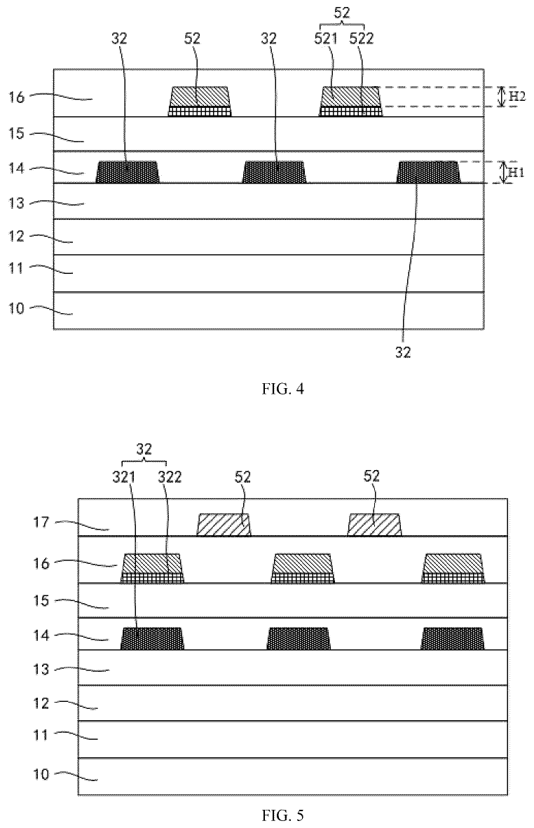

Please refer to FIG. 1 to FIG. 5. FIG. 1 is a schematic plan view of a first structure of a driving backplane provided in an embodiment of the present application. FIG. 2 is a schematic diagram of a structure of partial films in a driving backplane provided in an embodiment of the present application. FIG. 3 is a schematic diagram of a detailed structure in a fan-out area in FIG. 1. FIG. 4 is a schematic diagram of a first cross-sectional structure of the fan-out area taken along a line M-M′ in FIG. 3. FIG. 5 is a schematic diagram of a second cross-sectional structure of the fan-out area taken along the line M-M′ in FIG. 3. Referring to FIG. 1 and FIG. 2, the driving backplane 100 includes a display area AA and a non-display area BA located on a side of the display area AA. Multiple sub-pixels SPs are arranged in an array in the display area AA. For example, multiple sub-pixel SPs are arranged to be sequential in a first direction X and in a second direction Y. The first direction X is different from the second direction Y. An angle between the first direction X and the second direction Y is greater than 0 degrees and less than or equal to 90 degrees. For example, the first direction X is perpendicular to the second direction Y. That is, the first direction X is a row direction, and the second direction Y is a column direction. Each of the sub-pixels SPs includes a polysilicon transistor 1, an oxide transistor 2, and a storage capacitor C1. The non-display area BA includes a fan-out area SA arranged to be close to the display area AA, and the fan-out area SA is configured to fan out various signal lines in the display area AA.

The driving backplane 100 further includes a substrate 10 as well as a first semiconductor layer 20, a first conductive layer 30, a second semiconductor layer 40, and a second conductive layer 50 arranged on the substrate 10. The first semiconductor layer 20 is arranged on a side of the substrate 10, and the first semiconductor layer 20 includes an active part 21 of a polysilicon transistor 1. The first conductive layer 30 is arranged on a side, of the first semiconductor layer 20, away from the substrate 10. The first conductive layer 30 includes a gate 31 of the polysilicon transistor 1, and the gate 31 of the polysilicon transistor 1 is arranged to be corresponding to the active part 21 of the polysilicon transistor 1. The second semiconductor layer 40 is arranged on a side, of the first conductive layer 30, away from the substrate 10. The second semiconductor layer 40 includes a first electrode plate 42 of a storage capacitor C1 and an active part 41 of an oxide transistor 2. The first electrode plate 42 of the storage capacitor C1 is arranged to be corresponding to the gate 31 of the polysilicon transistor 1. The second conductive layer 50 is arranged on a side, of the second semiconductor layer 40, away from the substrate 10. The second conductive layer 50 includes a gate 51 of the oxide transistor 2, and the gate 51 of the oxide transistor 2 is arranged to be corresponding to the active part 41 of the oxide transistor 2. As such, by setting the first electrode plate 42 of the storage capacitor C1 and the active part 41 of the oxide transistor 2 in the same layer, a conductive layer between the second semiconductor layer 40 and the first conductive layer 30 can be removed, so that film layers of the driving backplane 100 can be simplified, the preparation process can be simplified, the preparation efficiency can be improved, and the production cost can be reduced.

Specifically, the driving backplane 100 further includes a third conductive layer 60 and a fourth conductive layer 70. The third conductive layer 60 is arranged on the side, of the second conductive layer 50, away from the substrate 10. The third conductive layer 60 includes a source 61 and a drain 62 of the polysilicon transistor 1 and a source 64 and a drain 63 of the oxide transistor 2. The fourth conductive layer 70 is arranged between the substrate 10 and the first semiconductor layer 20. The fourth conductive layer 70 includes a first light-shielding part 71 and a second light-shielding part 72. The first light-shielding part 71 is arranged to be corresponding to the active part 21 of the polysilicon transistor 1, and the second light-shielding part 72 is arranged to be corresponding to the active part 41 of the oxide transistor 2. Absolutely, the driving backplane 100 further includes an insulating layer between each conductive layer and the semiconductor layer.

Specifically, referring to FIG. 2, the fourth conductive layer 70 is arranged on a side of the substrate 10, and a first buffer layer 11 and a second buffer layer 12 are arranged between the fourth conductive layer 70 and the first semiconductor layer 20. The first buffer layer 11 is covered on the fourth conductive layer 70 and the substrate 10, and the second buffer layer 12 is covered on the first buffer layer 11. Optionally, the substrate 10 can be a substrate made of an inorganic material or a substrate made of an organic material. For example, in an embodiment of the present application, the material of the substrate 10 can be sodium calcium glass, quartz glass, sapphire glass, and other glass materials, or can be stainless steel, aluminum, nickel, and other metal materials. In another embodiment of the present application, the substrate 10 can also be a flexible substrate. For example, the material of substrate 10 can be polyimide (PI). The substrate 10 can also be a composite of multilayer materials. The first buffer layer 11 and the second buffer layer 12 can be inorganic films, such as SiNx, SiOx or their composite layers. The material of the fourth conductive layer 70 includes metal materials with light-shielding properties.

The first semiconductor layer 20 is arranged on the second buffer layer 12. The material of the first semiconductor layer 20 includes semiconductor materials such as polycrystalline silicon. The active part 21, of the polysilicon transistor 1, formed by the first semiconductor layer 20 includes a first channel part 211 and a first source contact part 212 and a first drain contact part 213 located on opposite sides of the first channel part 211. The first light-shielding part 71 is arranged to be corresponding to at least the first channel part 211 to shield light for the first channel part 211.

A first insulating layer 13 is arranged between the first semiconductor layer 20 and the first conductive layer 30. The material of the first insulating layer 13 includes inorganic materials such as SiNx and SiOx. The materials of the first conductive layer 30 include metal materials with conductive properties, such as molybdenum. The gate 31 formed by the first conductive layer 30 is arranged to be corresponding to the first channel 211.

A second insulating layer 14 is arranged between the first conductive layer 30 and the second semiconductor layer 40. The materials of the second insulating layer 14 include inorganic materials such as SiNx and SiOx. The materials of the second semiconductor layer 40 include metal oxide semiconductor materials, such as Indium Gallium Zinc Oxide (IGZO). The active part 41 of the oxide transistor 2 and the first electrode plate 42 of the storage capacitor C1 are formed on the second semiconductor layer 40. The active part 41 of the oxide transistor 2 includes a second channel part 411, and a second source contact part 412 and the second drain contact part 413 both located on opposite sides of the second channel part 411. The second light-shielding part 72 is arranged to be corresponding to at least the second channel part 411 to shield light for the second channel part 411. The first electrode plate 42 of the storage capacitor C1 is arranged to be corresponding to the gate 31 of the polysilicon transistor 1 to form the storage capacitor C1. Absolutely, in some embodiments, the second light-shielding part 72 can also be electrically connected to the gate 51 of the oxide transistor 2 as a bottom gate of the oxide transistor 2.

A third insulating layer 15 is arranged between the second semiconductor layer 40 and the second conductive layer 50. The materials of the third insulating layer 15 include inorganic materials such as SiNx and SiOx. The materials of the second conductive layer 50 include metal materials with conductive properties, such as molybdenum, titanium, etc., that is, the second conductive layer 50 can be formed by a two-layer metal layer of a titanium layer and a molybdenum layer. The molybdenum layer is located on a side, of the titanium layer, away from the substrate 10, and the titanium layer is configured to block hydrogen in an upper layer to avoid affecting the active part 41.

A fourth insulating layer 16 is arranged between the second conductive layer 50 and the third conductive layer 60. The materials of the fourth insulating layer 16 include inorganic materials such as SiNx and SiOx. An open hole 161 is formed in the fourth insulating layer 16. The materials of the third conductive layer 60 include conductive metals such as titanium, aluminum, and copper. A source 61 and a drain 62 of polysilicon transistor 1, and a source 64 and a drain 63 of oxide transistor 2 are formed on the third conductive layer 60. The source 61 of the polysilicon transistor 1 is connected with the first source contact 212, the drain 62 of the polysilicon transistor 1 is connected with the first drain contact 213, the source 64 of the oxide transistor 2 is connected with the second source contact 412, and the drain 63 of the oxide transistor 2 is connected with the second drain contact 413.

The driving backplane 100 further includes a fifth conductive layer 80 and a sixth conductive layer 90. The fifth conductive layer 80 is located on a side, of the third conductive layer 60, away from the substrate 10, and the sixth conductive layer 90 is located on a side, of the fifth conductive layer 80, away from the substrate 10. A first flat layer 17 is arranged between the third conductive layer 60 and the fifth conductive layer 80. The materials of the first flat layer 17 include organic materials, and the first flat layer 17 is filled in the open hole 161. The materials of the fifth conductive layer 80 is the same as the materials of the third conductive layer 60. The fifth conductive layer 80 forms a transfer electrode 81, and the transfer electrode 81 is connected to the drain 62 of the polysilicon transistor 1.

A second flat layer 18 is arranged between the fifth conductive layer 80 and the sixth conductive layer 90. The material of the second flat layer 18 include an organic material. The materials of the sixth conductive layer 90 include transparent conductive materials such as indium tin oxide. A first electrode 91 is formed on the sixth conductive layer 90, and the first electrode 91 is connected with the transfer electrode 81.

The driving backplane 100 further includes a third flat layer 19 and a retaining wall 92. The material of the third flat layer 19 includes an organic material. The third flat layer 19 is covered on the sixth conductive layer 90 and the second flat layer 18, and an opening 191 is formed in a position, of the third flat layer 19, corresponding to the first electrode 91, and the opening 191 exposes part of the first electrode 91. The retaining wall 92 is arranged on the third flat floor 19 and is located on a peripheral side of the opening 191.

Referring to FIG. 3, the fan-out area SA is provided with a first fan-out wiring 32 and a second fan-out wiring 52 arranged alternately. The first fan-out wiring 32 is located in at least one layer of the first conductive layer 30 or the second conductive layer 50, and the second fan-out wiring 52 is located in at least one layer of the second conductive layer 50 or the third conductive layer 60. The first fan-out wiring 32 and the second fan-out wiring 52 are located in different layers, and an impedance of the first fan-out wiring 32 is equal to an impedance of the second fan-out wiring 52, so as to improve the display uniformity.

In an embodiment, the first fan-out wiring 32 is located in the first conductive layer 30, the second fan-out wiring 52 is located in the second conductive layer 50. That is, the first conductive layer 30 further includes the first fan-out wiring 32 located in the fan-out area SA, and the second conductive layer 50 further includes the second fan-out wiring 52 located in the fan-out area SA. The first fan-out wiring 32 and the second fan-out wiring 52 are staggered in the first direction X, and an impedance of the first fan-out wiring 32 is equal to an impedance of the second fan-out wiring 52, so as to improve the display uniformity.

A ratio of a length of the first fan-out wiring 32 to a cross-sectional area of the first fan-out wiring is a first ratio, a ratio of a length of the second fan-out wiring 52 to a cross-sectional area of the second fan-out wiring is a second ratio, and the second ratio is equal to the first ratio, so that the impedance of the first fan-out wiring 32 is equal to the impedance of the second fan-out wiring 52. In addition, the fan-out area SA includes multiple first fan-out wirings 32 and multiple second fan-out wirings 52. The impedance of each of the first fan-out wirings 32 is the same, and the impedance of each of the second fan-out wirings 52 is the same.

Optionally, with reference to FIG. 4, a width of the first fan-out wiring 32 is equal to a width of the second fan-out wiring 52. The second fan-out wiring 52 includes a blocking part 522 and a conductive part 521 located on a side, of the blocking part 522, away from the substrate 10. A thickness H2 of the conductive part 521 is equal to a thickness H1 of the first fan-out wiring 32. The material of the conductive part 521 include molybdenum, materials of the blocking part 522 include titanium, and the materials of the first fan-out wiring 32 are the same as the materials of the conductive part 521.

An orthographic projection, of the first fan-out wiring 32, on the substrate 10 is separated from an orthographic projection, of the second fan-out wiring 52, on the substrate 10, that is, no overlap is between the orthographic projection, of the first fan-out wiring 32, on the substrate 10 and the orthographic projection, of the second fan-out wiring 52, on the substrate 10, so that a parasitic capacitance between the first fan-out wiring 32 and the second fan-out wiring 52 can be reduced. In addition, the present application uses the first conductive layer 30 to form the first fan-out wiring 32, and the second conductive layer 50 to form the second fan-out wiring 52, and the first conductive layer 30 and the second conductive layer 50 are separated by two insulating layers of the second insulating layer 14 and the third insulating layer 15, and the second semiconductor layer 40, so that a distance between the first fan-out wiring 32 and the second fan-out wiring 52 can be increased, thereby further reducing the parasitic capacitance between the first fan-out wiring 32 and the second fan-out wiring 52, and improving the uniformity of the display.

In some other embodiments, an orthographic projection, of the first fan-out wiring 32, on the substrate 10 is at least partially overlapped with an orthographic projection, of the second fan-out wiring 52, on the substrate 10, so that an area occupied by the fan-out area SA in the non-display area BA can be reduced, thereby increasing a screen ratio.

In another embodiment, referring to FIG. 5, the first fan-out wiring 32 includes a first sub-wiring 321 located in the first conductive layer 30 and a second sub-wiring 322 located in the second conductive layer 50. The first sub-wiring 321 and the second sub-wiring 322 are connected in parallel, and the second fan-out wiring 52 is located in the third conductive layer 60. That is, the first conductive layer 30 further includes the first sub-wiring 321 located in the fan-out area SA, the second conductive layer 50 further includes the second sub-wiring 322 located in the fan-out area SA, and the third conductive layer 60 further includes the second fan-out wiring 52 located in the fan-out area SA. The second sub-wiring 322 is connected to the first sub-wiring 321 through multiple contact holes in the third insulating layer 15 to realize a parallel connection of the first sub-wiring 321 and the second sub-wiring 322 so as to reduce the impedance of the first fan-out wiring 32.

Optionally, an orthographic projection, of the first sub-wiring 321, on the substrate 10 overlaps with an orthographic projection, of the second sub-wiring 322, on the substrate 10, so that an area occupied by the first fan-out wiring 32 in the fan-out area SA can be reduced.

In some other embodiments, the first fan-out wiring 32 can be located in the first conductive layer 30, the second fan-out wiring 52 is located in the second conductive layer 50 and the third conductive layer 60; or, the first fan-out wiring 32 can be located in the first conductive layer 30, the second fan-out wiring 52 is located in the third conductive layer 60; or, the first fan-out wiring 32 can be located in the second conductive layer 50, and the second fan-out wiring 52 is located in the third conductive layer 60.

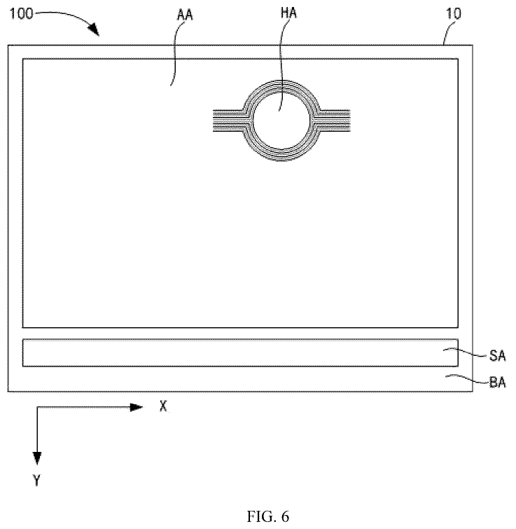

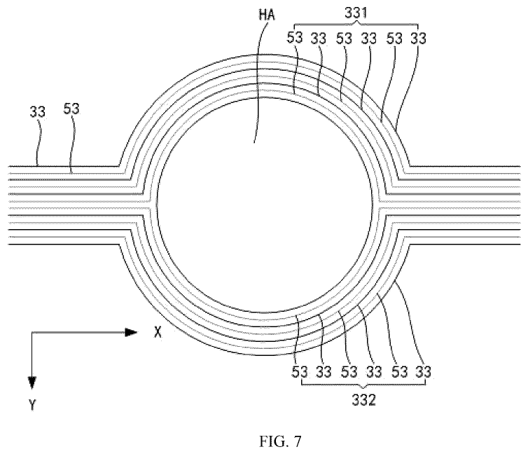

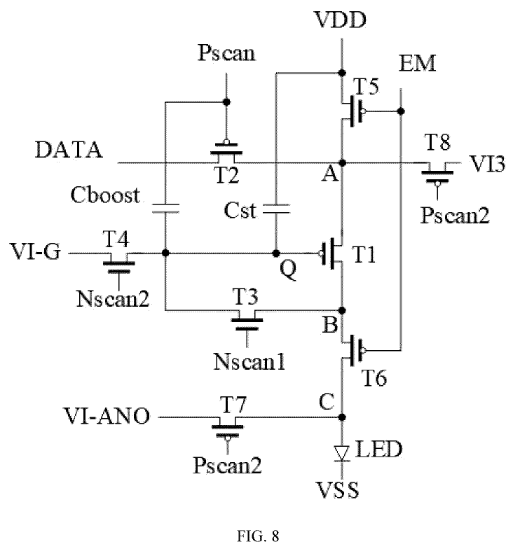

In an embodiment, referring to FIG. 1 to FIG. 8, FIG. 6 is a schematic plan view of a second structure of a driving backplane provided in an embodiment of the present application, FIG. 7 is a schematic diagram of a detailed structure of an edge wiring of a holing area in FIG. 6, and FIG. 8 is a circuit diagram of a sub-pixel provided in an embodiment of the present application. Referring to FIG. 6, different from the embodiments described above, the driving backplane 100 further includes a holing area HA arranged in the display area AA. The holing area HA is formed by digging holes in the driving backplane 100, and a camera and other functional components can be arranged below the holing area HA. The holing area HA is configured to transmit light and improve a lighting effect of functional components such as the camera.

Referring to FIG. 7, the first conductive layer 30 further includes a first winding line 33 located in the display area AA, and the second conductive layer 50 further includes a second winding line 53 located in the display area AA. The first winding line 33 and the second winding line 53 are extended X along the first direction. The driving backplane 100 further includes a first winding line group 331 and a second winding line group 332. The first winding line group 331 is configured to cooperate with the second winding line group 332 to surround the holing area HA. The first winding line group 331 and the second winding line group 332 both include multiple first winding lines 33 and second winding lines 53 alternately arranged in the second direction Y. The first winding line group 331 and the second winding line group 332 are symmetrically arranged to be corresponding to the holing area HA.

Optionally, a gap is provided between an orthographic projection, of the first winding line 33, on the substrate 10 and an orthographic projection, of the second winding line 53, on the substrate 10, that is, the orthographic projection, of the first winding line 33, on the substrate 10 and the orthographic projection, of the second winding line 53, on the substrate 10 do not overlap, so that the parasitic capacitance between the first winding line 33 and the second winding line 53 can be reduced. In addition, the present application uses the first conductive layer 30 to form the first winding line 33, and the second conductive layer 50 to form the second winding line 53, and the first conductive layer 30 and the second conductive layer 50 are separated by two insulating layers including the second insulating layer 14 and the third insulating layer 15 and the second semiconductor layer 40, so that a distance between the first winding line 33 and the second winding line 53 can be increased, thereby further reducing the parasitic capacitance between the first winding line 33 and the second winding line 53, and improving the uniformity of the display.

The first winding line 33 and the second winding line 53 can be various control signal lines or scanning lines on the driving backplane 100. Specifically, with reference to FIG. 8, each of the sub-pixels SPs includes eight transistors and two capacitors is taken as an example to explain. The eight transistors are a driving transistor T1, a switching transistor T2, a compensation transistor T3, a first initialization transistor T4, a first light-emitting control transistor T5, a second light-emitting control transistor T6, a second initialization transistor T7, and a third initialization transistor T8. The two capacitors are a first capacitor Cst and a second capacitor Cboost.

Specifically, a gate of the switching transistor T2 is connected to a first scan signal line Pscan, and a first electrode of the switching transistor T2 is connected to a data line DATA.

A first electrode of the driving transistor T1 is connected to a second electrode of the switching transistor T2 at a first node A.

A gate of the compensation transistor T3 is connected to a second scanning signal line Nscan1, a first electrode of the compensation transistor T3 is connected to a gate of the driving transistor T1 at a second node Q, and a second electrode of the compensation transistor T3 is connected to a second electrode of the driving transistor T1.

A gate of the first initialization transistor T4 is connected to a third scanning signal line Nscan2, a first electrode of the first initialization transistor T4 is connected to a first initialization signal line VI-G, and a second electrode of the first initialization transistor T4 is connected to the gate of the driving transistor T1 at the second node Q.

A gate of the first light-emitting control transistor T5 is connected to a light-emitting control signal line EM, a first electrode of the first light-emitting control transistor T5 is connected to a high-potential power line VDD, and a second electrode of the first light-emitting control transistor T5 is connected to the first electrode of the driving transistor T1 at the first node A.

A gate of the second light-emitting control transistor T6 is connected to the light-emitting control signal line EM, and a first electrode of the second light-emitting control transistor T6 and the second electrode of the driving transistor T1 are connected to a third node B.

A gate of the second initialization transistor T7 is connected to a fourth scanning signal line Pscan2, a first electrode of the second initialization transistor T7 is connected to a second initialization signal line VI-ANO, and a second electrode of the second initialization transistor T7 is connected to a second electrode of the second light-emitting control transistor T6 at the fourth node C.

A gate of the third initialization transistor T8 is connected to the fourth scanning signal line Pscan2, a first electrode of the third initialization transistor T8 is connected to a third initialization signal line VI3, and a second electrode of the third initialization transistor T8 is connected to the first electrode of the driving transistor T1 at the first node A.

One electrode plate of the first capacitor Cst is connected to the high potential power line VDD, and another plate of the first capacitor Cst is connected to the gate of the driving transistor T1 at the second node Q.

One plate of the second capacitor Cboost is connected to the first scan signal line Pscan, and the other plate of the second capacitor Cboost is connected to the second electrode of the first initialization transistor T4.

The polysilicon transistor 1 includes the switching transistor T2, the driving transistor T1, the first light-emitting control transistor T5, the second light-emitting control transistor T6, the second initialization transistor T7, and the third initialization transistor T8. The oxide transistor 2 includes the compensation transistor T3 and the first initialization transistor T4. The first capacitor Cst is a storage capacitor C1, and the second capacitor Cboost is a boost capacitor. The first winding line 33 and the second winding line 53 can be respectively at least one of the first scanning signal line Pscan, the second scanning signal line Nscan1, the third scanning signal line Nscan2, the fourth scanning signal line Pscan2, the light-emitting control signal line EM, the first initialization signal line VI-G, the second initialization signal line VI-ANO, or the third initialization signal line VI3.

Optionally, the first electrode plate 42 of the storage capacitor C1 is arranged to be corresponding to the gate of the driving transistor T1.

It should be noted that the first electrode of the transistor in the embodiment described above is the source and the second electrode is the drain; or the first electrode of the transistor in the embodiment described above is the drain and the second electrode is the source. The first scan signal line Pscan, the second scan signal line Nscan1, the third scan signal line Nscan2, the fourth scan signal line Pscan2 and the light-emitting control signal line EM can be respectively connected to different gate driving circuits. Specifically, five sets of gate driving circuits can be respectively configured to output signals to the first scan signal line Pscan, the second scan signal line Nscan1, the third scan signal line Nscan2, the fourth scan signal line Pscan2, and the light-emitting control signal line EM. The gate driving circuit connected to the first scan signal line Pscan can adopt bilateral drive, and other gate driving circuits adopt unilateral drive.

Based on the same invention idea, the present application further provides a display panel, and the display panel includes a light-emitting component and a driving backplane 100 of one of the embodiments described above. The light-emitting component is arranged on the driving backplane 100, and the driving backplane 100 is configured to drive the light-emitting component to emit light.

In the embodiments described above, the description of each embodiment has its own emphasis, and the part that is not detailed in one embodiment can be seen in the relevant description of other embodiments.

The above provides a detailed introduction to the embodiments of the present application. Specific examples are applied in this article to explain the principles and implementation methods of the present disclosure. The explanations of the above embodiments are only configured to help understand the technical solutions and their core ideas of the present disclosure. Those skilled in the art should understand that they can still modify the technical solutions recorded in the aforementioned embodiments, or equivalently replace some of the technical features; and these modifications or replacements do not separate the essence of the corresponding technical solutions from the scope of the technical solutions of the various embodiments of the present disclosure.

The above embodiments of the present application are introduced in detail. In this paper, the principle and implementation solution of the present application are expounded by using specific examples. The explanations of the above embodiments are only configured to help understand the technical solutions and their core ideas of the present disclosure. Those skilled in the art should understand that they can still modify the technical solutions recorded in the above embodiments, or equivalently replace some of the technical features; and these modifications or replacements do not separate the essence of the corresponding technical solutions from the scope of the technical solutions of the various embodiments of the present disclosure.

What is claimed is:

1. A driving backplane, comprising a display area and a non-display area located on a side of the display area, the display area being provided with a plurality of sub-pixels arranged in an array, each of the sub-pixels comprising a polysilicon transistor, an oxide transistor, and a storage capacitor; the driving backplane further comprising:
a substrate;
a first semiconductor layer, being arranged on a side of the substrate, the first semiconductor layer comprising an active part of the polysilicon transistor;
a first conductive layer, being arranged on a side, of the first semiconductor layer, away from the substrate, the first conductive layer comprising a gate of the polysilicon transistor;
a second semiconductor layer, being arranged on a side, of the first conductive layer, away from the substrate, the second semiconductor layer comprising a first electrode plate of the storage capacitor and an active part of the oxide transistor, and the first electrode plate of the storage capacitor being arranged to be corresponding to the gate of the polysilicon transistor;
a second conductive layer, being arranged on a side, of the second semiconductor layer, away from the substrate, the second conductive layer comprising a gate of the oxide transistor; and
a third conductive layer, being arranged on a side, of the second conductive layer, away from the substrate, the third conductive layer comprising a source and a drain of the polysilicon transistor, and a source and a drain of the oxide transistor;
wherein, the non-display area comprises a fan-out area arranged to be close to the display area, the fan-out area is provided with a first fan-out wiring and a second fan-out wiring arranged alternately, the first fan-out wiring is located at least one layer of the first conductive layer or the second conductive layer, the second fan-out wiring is located at least one layer of the second conductive layer or the third conductive layer, the first fan-out wiring and the second fan-out wiring are located in different layers, and an impedance of the first fan-out wiring is equal to an impedance of the second fan-out wiring.

2. The driving backplane of claim 1, wherein the first fan-out wiring is located in the first conductive layer, the second fan-out wiring is located in the second conductive layer, the ratio of the length of the first fan-out wiring to its cross-sectional area is a first ratio, the ratio of the length of the second fan-out wiring to a cross-sectional area of a second fan-out wiring is the second ratio, and the second ratio is equal to the first ratio.

3. The driving backplane of claim 2, wherein the second fan-out wiring comprises a blocking part and a conductive part located on a side, of the blocking part, away from the substrate, and a thickness of the conductive part is equal to a thickness of the first fan-out wiring.

4. The driving backplane of claim 3, wherein the material of the conductive part comprised molybdenum, the material of the blocking part comprises titanium, and the material of the first fan-out wiring is same as the material of the conductive part.

5. The driving backplane of claim 1, wherein the first fan-out wiring comprises a first sub-wiring located in the first conductive layer and a second sub-wiring located in the second conductive layer, the first sub-wiring and the second sub-wiring are connected in parallel, and the second fan-out wiring is located in the third conductive layer.

6. The driving backplane of claim 5, wherein an orthographic projection, of the first sub-wiring, on the substrate overlaps with an orthographic projection, of the second sub-wiring, on the substrate.

7. The driving backplane of claim 1, wherein an orthographic projection, of the first fan-out wiring, on the substrate is at least partially overlapped with an orthographic projection, of the second fan-out wiring, on the substrate.

8. The driving backplane of claim 1, wherein the driving backplane further comprises a fourth conductive layer arranged between the substrate and the first semiconductor layer, and the fourth conductive layer comprises a first light-shielding part arranged to be corresponding to the active part of the polysilicon transistor and a second light-shielding part arranged to be corresponding to the active part of the oxide transistor.

9. The driving backplane of claim 8, wherein the second light-shielding part is electrically connected to a gate of the oxide transistor.

10. The driving backplane of claim 1, wherein the first fan-out wiring and the second fan-out wiring are staggered in the first direction;
the driving backplane further comprises a holing area arranged in the display area, the first conductive layer further comprises a first winding line located in the display area, the second conductive layer further comprises a second winding line located in the display area, and both the first winding line and the second winding line extend along the first direction; and
the driving backplane further comprises a first winding line group and a second winding line group, the first winding line group is configured to cooperate with the second winding line group to surround the holing area, the first winding line group and the second winding line group both comprise a plurality of first winding lines and second winding lines alternately arranged in a second direction, the first direction is different from the second direction, and an angle between the second direction and the first direction is greater than 0 degree and less than or equal to 90 degrees.

11. The driving backplane of claim 10, wherein a gap is provided between an orthographic projection, of the first winding, on the substrate and an orthographic projection, of the second winding, on the substrate.

12. The driving backplane of claim 10, wherein each sub-pixel further comprises:
a switching transistor, wherein a gate of the switching transistor is connected with a first scanning signal line, and a first electrode of the switching transistor is connected with a data line;
a driving transistor, wherein a first electrode of the driving transistor and a second electrode of the switching transistor are connected to a first node;
a compensation transistor, wherein a gate of the compensation transistor is connected with a second scanning signal line, a first electrode of the compensation transistor is connected with a gate of the driving transistor at a second node, and a second electrode of the compensation transistor is connected with a second electrode of the driving transistor;
a first initialization transistor, wherein a gate of the first initialization transistor is connected with a third scanning signal line, a first electrode of the first initialization transistor is connected with a first initialization signal line, and a second electrode of the first initialization transistor is connected with a gate of the driving transistor at the second node;
a first light-emitting control transistor, wherein a gate of the first light-emitting control transistor is connected with a light-emitting control signal line, a first electrode of the first light-emitting control transistor is connected with a high potential power line, and a second electrode of the first light-emitting control transistor is connected with the first electrode of the driving transistor at the first node;
a second light-emitting control transistor, wherein a gate of the second light-emitting control transistor is connected with the light-emitting control signal line, and a first electrode of the second light-emitting control transistor is connected with a second electrode of the driving transistor at a third node;
a second initialization transistor, wherein a gate of the second initialization transistor is connected with a fourth scanning signal line, a first electrode of the second initialization transistor is connected with a second initialization signal line, and a second electrode of the second initialization transistor is connected with a second electrode of the second light-emitting control transistor at a fourth node;
a third initialization transistor, wherein a gate of the third initialization transistor is connected with the fourth scanning signal line, a first electrode of the third initialization transistor is connected with a third initialization signal line, and a second electrode of the third initialization transistor is connected with the first electrode of the driving transistor at the first node;
a first capacitor, wherein one electrode plate of the first capacitor is connected with the high potential power line, and another electrode plate of the first capacitor is connected with the gate of the driving transistor at the second node; and
a second capacitor, wherein one electrode plate of the second capacitor is connected with the first scanning signal line, and another electrode plate of the second capacitor is connected with the second electrode of the first initialization transistor;
wherein, the polysilicon transistor comprises the switching transistor, the driving transistor, the first light-emitting control transistor, the second light-emitting control transistor, the second initialization transistor, and the third initialization transistor; the oxide transistor comprises the compensation transistor and the first initialization transistor; and the first capacitor is the storage capacitor, and the second capacitor is a boost capacitor.

13. The driving backplane of claim 12, wherein the first winding and the second winding can be respectively at least one of the first scanning signal line, the second scanning signal line, the third scanning signal line, the fourth scanning signal line, the light-emitting control signal line, the first initialization signal line, the second initialization signal line, or the third initialization signal line.

14. The driving backplane of claim 12, wherein a first electrode plate of the storage capacitor is arranged to be corresponding to the gate of the driving transistor.

15. A display panel, comprising a light-emitting component and a driving backplane, the light-emitting component being arranged on the driving backplane; the driving backplane comprising a display area and a non-display area located on a side of the display area, the display area being provided with a plurality of sub-pixels arranged in an array, each of the sub-pixels comprising a polysilicon transistor, an oxide transistor, and a storage capacitor; the driving backplane further comprising:
a substrate;
a first semiconductor layer, being arranged on a side of the substrate, the first semiconductor layer comprising an active part of the polysilicon transistor;
a first conductive layer, being arranged on a side, of the first semiconductor layer, away from the substrate, the first conductive layer comprising a gate of the polysilicon transistor;
a second semiconductor layer, being arranged on a side, of the first conductive layer, away from the substrate, the second semiconductor layer comprising a first electrode plate of the storage capacitor and an active part of the oxide transistor, and the first electrode plate of the storage capacitor being arranged to be corresponding to the gate of the polysilicon transistor;
a second conductive layer, being arranged on a side, of the second semiconductor layer, away from the substrate, the second conductive layer comprising a gate of the oxide transistor; and
a third conductive layer, being arranged on a side, of the second conductive layer, away from the substrate, the third conductive layer comprising a source and a drain of the polysilicon transistor, and a source and a drain of the oxide transistor;
wherein, the non-display area comprises a fan-out area arranged to be close to the display area, the fan-out area is provided with a first fan-out wiring and a second fan-out wiring arranged alternately, the first fan-out wiring is located at least one layer of the first conductive layer or the second conductive layer, the second fan-out wiring is located at least one layer of the second conductive layer or the third conductive layer, the first fan-out wiring and the second fan-out wiring are located in different layers, and an impedance of the first fan-out wiring is equal to an impedance of the second fan-out wiring.

16. The display panel of claim 15, wherein the first fan-out wiring is located in the first conductive layer, the second fan-out wiring is located in the second conductive layer, the ratio of the length of the first fan-out wiring to its cross-sectional area is the first ratio, the ratio of the length of the second fan-out wiring to a cross-sectional area of the second fan-out wiring is the second ratio, and the second ratio is equal to the first ratio.

17. The display panel of claim 15, wherein the first fan-out wiring comprises a first sub-wiring located in the first conductive layer and a second sub-wiring located in the second conductive layer, the first sub-wiring and the second sub-wiring are connected in parallel, and the second fan-out wiring is located in the third conductive layer.

18. The display panel of claim 15, wherein the driving backplane further comprises a fourth conductive layer arranged between the substrate and the first semiconductor layer, and the fourth conductive layer comprises a first light-shielding part arranged to be corresponding to the active part of the polysilicon transistor and a second light-shielding part arranged to be corresponding to the active part of the oxide transistor.

19. The display panel of claim 15, wherein the first fan-out wiring and the second fan-out wiring are staggered in the first direction;
the driving backplane further comprises a holing area arranged in the display area, the first conductive layer further comprises a first winding line located in the display area, the second conductive layer further comprises a second winding line located in the display area, and both the first winding line and the second winding line extend along the first direction; and
the driving backplane further comprises a first winding line group and a second winding line group, the first winding line group is configured to cooperate with the second winding line group to surround the holing area, the first winding line group and the second winding line group both comprise a plurality of first winding lines and second winding lines alternately arranged in a second direction, the first direction is different from the second direction, and an angle between the second direction and the first direction is greater than 0 degree and less than or equal to 90 degrees.

20. The display panel of claim 19, wherein a gap is provided between an orthographic projection, of the first winding, on the substrate and an orthographic projection, of the second winding, on the substrate.
